(19) United States
(12) Patent Application Publication
(10) Pub. No.: US 2012/0008269 A1
(43) Pub. Date: Jan. 12, 2012

(54) PROTECTIVE COVER FOR A MOBILE COMPUTING DEVICE, SYSTEMS INCLUDING PROTECTIVE COVERS, AND ASSOCIATED METHODS

(76) Inventor: David Gengler, Draper, UT (US)

(21) Appl. No.: 12/954,841

(22) Filed: Nov. 26, 2010

Related U.S. Application Data
(63) Continuation-in-part of application No. 29/379,842, filed on Nov. 24, 2010.
Application No. 29/379,842 is a continuation-in-part of application No. 29/378,952, filed on Nov. 11, 2010.
Application No. 29/378,952 is a continuation-in-part of application No. 29/379,058, filed on Nov. 12, 2010.
Application No. 29/379,058 is a continuation-in-part of application No. 12/832,845, filed on Jul. 8, 2010.
Application No. 12/832,845 is a continuation-in-part of application No. 29/379,837, filed on Nov. 24, 2010.
Application No. 29/379,837 is a continuation-in-part of application No. 29/378,952, filed on Nov. 11, 2010.
Application No. 29/378,952 is a continuation-in-part of application No. 29/379,839, filed on Nov. 24, 2010.
Application No. 29/379,839 is a continuation-in-part of application No. 29/379,058, filed on Nov. 12, 2010.

(51) Int. Cl. H05K 5/00; H05K 5/03

(52) U.S. Cl. 361/679.09; 206/320; 361/679.55

(57) ABSTRACT

A hard protective cover is configured to protect the display, or screen, and optionally the housing of a mobile computing device while the mobile computing device is not in use. When positioned over the display of a mobile computing device, the hard protective cover may provide protection without substantially increasing the thickness or other dimensions of the mobile computing device. The hard protective cover may also be configured to orient the mobile computing device in a working orientation and, in some embodiments, may enhance or add to the functionality of the mobile computing device. Systems including assemblies of a protective cover and a mobile computing device and, optionally, external devices, are also disclosed, as are methods for using hard protective covers.

### CROSS-REFERENCE TO RELATED APPLICATIONS

This application is a continuation-in-part of (i) U.S. Design patent application No. 29/379,842, filed Nov. 24, 2010, for PROTECTIVE COVER WITH RECESSED EDGE, AND CONFIGURED FOR USE WITH A MOBILE COMPUTING DEVICE, pending; which is a continuation-in-part of (ii) U.S. Design patent application No. 29/378,952, filed on Nov. 11, 2010, for PROTECTIVE COVER FOR A MOBILE COMPUTING DEVICE (hereinafter “the '952 Application”), pending, and of (iii) U.S. Design patent application No. 29/379,058, filed on Nov. 12, 2010, for PROTECTIVE COVER, INCLUDING KEYBOARD, FOR A MOBILE COMPUTING DEVICE (hereinafter “the '058 Application”), pending; both of which are continuations-in-part of (iv) U.S. patent application Ser. No. 12/832,845, filed on Jul. 8, 2010, for SYSTEM AND APPARATUS FOR PROTECTING A MOBILE DEVICE, pending. This application is also a continuation-in-part of (v) U.S. Design patent application No. 29/379,837, filed Nov. 24, 2010, for SUPPORT ELEMENT OF A PROTECTIVE COVER FOR A MOBILE COMPUTING DEVICE, pending, which is a continuation-in-part of the '952 Application, and of (vi) U.S. Design patent application No. 29/379,839, filed Nov. 24, 2010, for SUPPORT ELEMENT OF A PROTECTIVE COVER FOR A MOBILE COMPUTING DEVICE, pending, which is a continuation-in-part of the '058 Application. The disclosures of all of the foregoing patent applications are hereby incorporated herein, in their entireties, by this reference.

### TECHNICAL FIELD

The present invention relates generally to protective covers for mobile computing devices and, more specifically, to hard covers for protecting the displays, or screens, and housings of mobile computing devices while the mobile computing devices are not in use. When positioned over the display of a mobile computing device, a protective cover of the present invention may provide protection without substantially increasing the thickness or other dimensions of the mobile computing device. The present invention also relates to systems including protective covers and mobile computing devices, as well as to methods for using mobile computing devices.

### RELATED ART

Since the advent of mobile computing, mobile computing devices have, over time, become increasingly portable, more readily useful, easier to use and more affordable. As a result of their portability, ready usefulness and ease-of-use, the frequency with which state-of-the-art mobile computing devices are used and the circumstances under which mobile computing devices are used are also ever-increasing. In fact, users who carry mobile computing devices often access them several times throughout the day.

Unfortunately, with repeated access and use, the potential for damaging (e.g., through wear-and-tear, dropping, etc.) fragile mobile computing devices is significant. And, although they are considered to be relatively affordable by historical standards, the monetary costs of mobile computing devices are still significant, particularly to many individual consumers. In addition, the repair or replacement of damaged mobile computing devices, and the restoration of data and applications (i.e., programs), require significant amounts of valuable time.

In an effort to protect mobile computing devices from damage, a variety of protective apparatuses and devices have been developed. For example, screen protectors protect the displays of mobile computing devices from scratches that may occur during normal use or transportation (e.g., in pockets, purses, daypacks, computer bags, cars, and all of the other various places that mobile computing devices may be left). Although screen protectors protect the displays of mobile computing devices from scratches, they often provide only minimal impact resistance to the displays if the mobile computing devices are dropped.

Protective “bumpers,” which surround the peripheral edges and, sometimes, the backs of mobile computing devices, are configured to absorb impact in the (not so infrequent) event that a mobile computing device is dropped. While protective bumpers may shield the peripheral edges of a mobile computing device from impact, they provide minimal, if any, impact protection to the typically fragile display of a mobile computing device.

Portfolio-type covers offer more comprehensive protection for mobile computing devices, provided that they remain closed upon impact. Nonetheless, portfolio-type covers are usually formed from pliable materials, such as vinyl or leather, which are sometimes supported by cardboard. As a result, while portfolio-type covers provide some impact protection to the displays of mobile computing devices, they do not provide optimal protection to the displays of mobile computing devices. Furthermore, the dimensions of portfolio-type covers are typically much greater than the corresponding dimensions of the mobile computing devices they are intended to protect—adding an inch or more to the height and width of a protected mobile computing device, and often increasing the overall thickness of the device by a factor of two or more. Thus, many portfolio-type covers render a protected mobile computing device more cumbersome that it would otherwise be, counteracting the desire for devices with minimal dimensions.

### SUMMARY

A protective cover that incorporates teachings of the present invention is configured to be placed over the display of a mobile computing device and to absorb any impact that may be directed toward the display of the mobile computing device. A protective cover of the present invention may be configured to provide optimal protection to a mobile computing device while posing only a minimal hindrance to use of the mobile computing device.

In various embodiments, a protective cover of the present invention includes a solid or substantially solid base, which is configured to be placed over the display of a mobile computing device. In addition to the base, a protective cover of the present invention may include at least one retention element protruding from a periphery of the base. The at least one retention element may be configured to engage at least a portion of an outer periphery of the mobile computing device and, in some embodiments, to absorb any impact against the periphery (or at least a covered portion of the periphery) of the mobile computing device. Together, the base and the at least one retention element define a receptacle for receiving at least a portion of a mobile computing device.

The base of a protective cover according to the present invention may also be configured to receive a mobile computing device and retain the same in such a way that the display of the mobile computing device may be accessed. In some embodiments, the receptacle may be configured to receive an edge of a mobile computing device, while a support element within the receptacle may be placed in an upright position to support the mobile computing device in a somewhat upright position (e.g., at an angle).

While the receptacles of some embodiments of protective covers according to the present invention are configured merely to receive a mobile computing device to protect its display (i.e., in a protected arrangement), and the receptacles of other embodiments of protective covers of the present invention are configured to protect the display of a mobile computing device and orient the mobile computing device for use (i.e., in a working arrangement), other embodiments of protective covers of the present invention include receptacles that carry elements that add to or enhance the functionality of a mobile computing device. Without limiting the scope of the present invention, a protective cover of the present invention may include a keyboard (e.g., a physical keyboard, etc.) that is easier to use than the virtual keyboards on the touch-screen displays of many mobile computing devices. Other non-limiting examples of accessories that may be carried by the receptacle of a protective cover of the present invention include batteries that may provide backup power for a mobile computing device, communication elements that may provide a mobile computing device with alternate and/or additional means of communication (e.g., USB or USB micro ports, HDMI ports, IEEE 1394 (i.e., FireWire, i.LINK, Lynx) interfaces, 8P8C jacks, etc.), peripheral memory devices (e.g., disk drives, hard drives, etc.) and other peripheral devices that may extend the functionality of a mobile computing device.

In another aspect, the present invention also includes mobile computing systems, which, in the most basic embodiments, include a mobile computing device and a protective cover of the present invention. In more complex embodiments, a mobile computing system may also include one or more accessories carried by the protective cover. In some embodiments, a mobile computing system of the present invention may also include external devices that communicate with the mobile computing device through one or more accessories carried by the protective cover.

In addition to protective covers and mobile computing systems, various methods are also within the scope of the present invention. For example, the present invention includes various embodiments of methods for protecting the displays of mobile computing devices from damage during storage or transportation. In such a method, the display of a mobile computing device is oriented over the receptacle and base of a protective cover. The mobile computing device is then inserted into the receptacle, with the display positioned against and substantially covered by the base. As the mobile computing device is introduced into the receptacle of the protective cover, in some embodiments, one or more retention elements of the protective cover may engage the mobile computing device to retain the mobile computing device within the receptacle and, thus, the hold the base of the protective cover in place over the display.

The present invention also includes methods for removing a protective cover from over the display of a mobile computing device. A feature of the mobile computing device (e.g., a portion of a peripheral edge of the mobile computing device, etc.) exposed beyond the protective cover may be engaged at the same time that an adjacent feature of the protective cover (e.g., an edge of periphery of the protective cover, etc.) is engaged. The engaged features may then be pulled in opposite or substantially opposite directions to remove the protective cover from over the display of the mobile computing device.

The protective cover may then be used to hold the mobile computing device in a desired position for use. In some embodiments, a support element associated with the protective cover may be oriented in an upright position (e.g., within the receptacle of the protective cover, etc.). The mobile computing device is then oriented in a desired manner (e.g., landscape, portrait, etc.) relative to the protective cover, with bottom edge (the edge depending upon the orientation of the mobile computing device) resting against the protective cover (e.g., within the receptacle of the protective cover, against a back side of the base of the protective cover, etc.), with a back side of the mobile computing device resting upon the support element.

In some embodiments, the mobile computing device may be positioned relative to the protective cover to enable a user to comfortably type using a keyboard (virtual or physical) of the mobile computing device. In other embodiments, the mobile computing device may be positioned at a more upright angle, which may facilitate viewing of the display of the mobile computing device without physically interacting with the display or any other feature (e.g., a physical keyboard, etc.) of the mobile computing device. Such a position may be useful for viewing video, for viewing the display while using a separate keyboard (e.g., a keyboard carried by the protective cover, etc.), or under a variety of other circumstances.

Other aspects, as well as the features and advantages of various aspects, of the present invention will become apparent to those of ordinary skill in the art through consideration of the ensuing description, the accompanying drawings and the appended claims.

### IN THE DRAWINGS

In the drawings:

FIG. 1 is a perspective view of the outside surface of an embodiment of protective cover of the present invention;

FIG. 2 is a plan view of the outside surface of the embodiment of protective cover illustrated by FIG. 1;

FIG. 3 is a perspective view of the inside surface of the embodiment of protective cover shown in FIG. 1;

FIG. 4 is a plan view of the inside surface of the embodiment of protective cover shown by FIG. 1;

FIG. 5 is a plan view of a bottom of the embodiment of protective cover depicted by FIG. 1;

FIG. 6 is a top plan view of an embodiment of support element of a protective cover of the present invention, showing the support element in a flattened, or collapsed position;

FIG. 7 is a plan view of a side edge of the embodiment of support element shown in FIG. 6;

FIG. 8 is a plan view of a front edge of the embodiment of support element illustrated by FIG. 6;

FIG. 9 is a plan view of a rear edge of the embodiment of support element depicted by FIG. 6;

FIG. 10 is a perspective representation of the embodiment of support element of FIG. 6 in a raised position;

FIG. 11 is a side plan view of the embodiment of support element illustrated by FIG. 6 in the raised position depicted by FIG. 10;

FIG. 12 is a top plan view of the embodiment of support element shown in FIG. 6 in the raised position illustrated by FIG. 10;

FIG. 13 is a bottom plan view of the embodiment of support element depicted by FIG. 6 in the raised position shown in FIG. 10;

FIG. 14 is a perspective view that illustrates an embodiment of a mobile computing device oriented in a substantially upright landscape working position relative to the embodiment of protective cover shown in FIG. 1;

FIG. 15 is a perspective view that illustrates an embodiment of a mobile computing device oriented in an inclined landscape working position relative to the embodiment of protective cover shown in FIG. 1;

FIG. 16 is a perspective view that illustrates an embodiment of a mobile computing device oriented in a substantially upright portrait working position relative to the embodiment of protective cover shown in FIG. 1;

FIG. 17 is a plan view showing an embodiment of a mobile computing device in a nested working orientation within the receptacle of the embodiment of protective cover shown in FIG. 1;

FIG. 18 is a perspective view of the outside surface of another embodiment of protective cover that incorporates teachings of the present invention;

FIG. 19 is a plan view of the outside surface of the embodiment of protective cover shown in FIG. 18;

FIG. 20 is a perspective view of the inside surface of the embodiment of protective cover illustrated by FIG. 18;

FIG. 21 is a plan view of the inside surface of the embodiment of protective cover depicted by FIG. 18;

FIG. 22 is a plan view of a side of the embodiment of protective cover of FIG. 18, showing a recess in the top edge of the side;

FIG. 23 is a perspective view showing an embodiment of a mobile computing device within a recess that communicates with the interior surface of the embodiment of protective cover depicted by FIG. 18;

FIG. 24 is a plan view of a bottom of the embodiment of protective cover shown in FIG. 18, illustrating a manner in which access to a communications port of an embodiment of a mobile computing device may be obtained as the mobile computing device is located within a receptacle of the protective cover;

FIG. 25 is a perspective view of the top of an embodiment of support element of a protective cover of the present invention, illustrating the support element in a folded, or collapsed, position;

FIG. 26 is a top plan view of the embodiment of support element depicted by FIG. 25;

FIG. 27 is a perspective view of the bottom of the embodiment of support element shown in FIG. 25;

FIG. 28 is a bottom plan view of the embodiment of support element shown by FIG. 25;

FIG. 29 is a plan view of a rear edge of the embodiment of support element illustrated by FIG. 25;

FIG. 30 is a plan view of a front edge of the embodiment of support element depicted by FIG. 25;

FIG. 31 is a side plan view of the embodiment of support element shown in FIG. 25;

FIG. 32 is a perspective view of the embodiment of support element of FIG. 25 is a raised position;

FIG. 33 is a side plan view of the embodiment of support element depicted by FIG. 25 in the raised position shown in FIG. 32;

FIG. 34 is a top plan view of the embodiment of support element illustrated by FIG. 25 in the raised position depicted by FIG. 32;

FIG. 35 is a bottom plan view of the embodiment of support element shown in FIG. 25 in the raised position illustrated by FIG. 32;

FIG. 36 illustrates an embodiment of a base that may be used to hold the embodiment of support element shown by FIG. 25 in the raised position depicted in FIG. 32;

FIG. 37 is a plan view showing the interior surface of the embodiment of protective cover illustrated by FIG. 18 with the embodiment of support element shown in FIG. 25 in the folded position;

FIG. 38 is a plan view showing the interior surface of the embodiment of protective cover illustrated by FIG. 18 with the embodiment of support element shown in FIG. 25 in the raised position; and

FIG. 39 is a perspective view showing an embodiment of mobile computing device in a substantially upright working orientation within the embodiment of protective cover depicted by FIG. 18.

### DETAILED DESCRIPTION

Protective covers according to the present invention are configured for use with mobile computing devices. Without limiting the scope of the present invention, the inventive protective covers may be used with so-called “slate” or “tablet” computers (e.g., the IPAD® available from Apple, Inc., etc.), smart phones, e-readers, hand-held multimedia devices (e.g., Apple's IPAD TOUCH®, etc.) or any other portable or mobile computing devices with displays that are configured to remain exposed whether or not the device is in use.

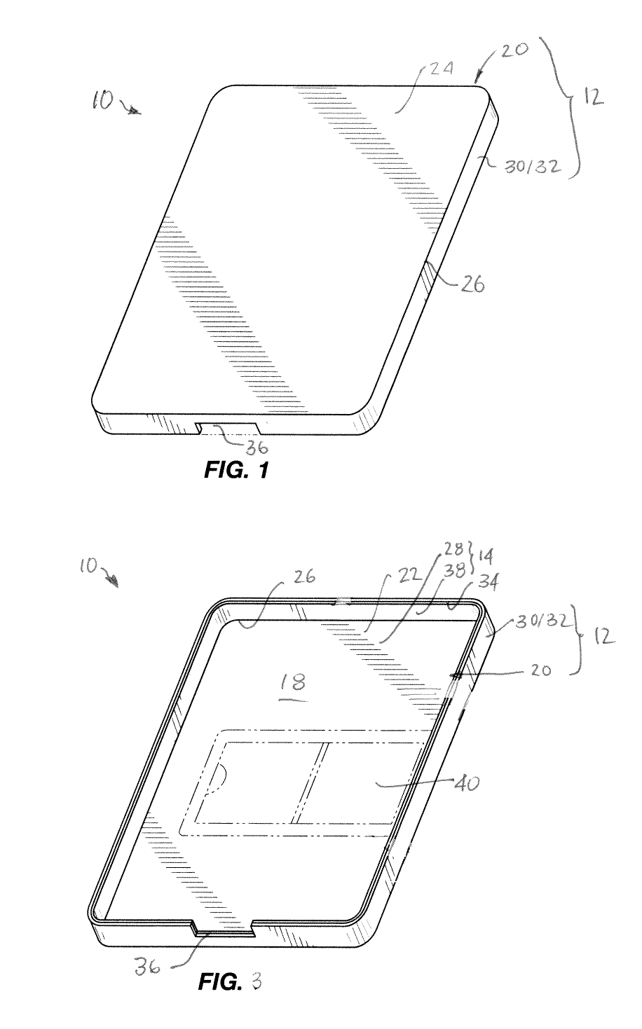

FIGS. 1-5 illustrate an embodiment of a protective cover 10 that incorporates teachings of the present invention. As shown, the protective cover 10 includes a base 20. In addition, the protective cover 10 may include at least one retention element 30.

The base 20 of the protective cover 10 is configured to be positioned over and to completely cover (as shown) or substantially cover (e.g., in embodiments that include perforations, etc.) the display of a mobile computing device (not shown). The base 20 of the protective cover includes an interior surface 22, which is configured to be placed adjacent to or against the display of a mobile computing device, and an opposite outer surface 24.

The at least one retention element 30 of the protective cover 10 is configured to engage part (e.g., a peripheral edge, a feature, etc.) of the mobile computing device (not shown). The at least one retention element 30 may comprise one or more peripheral elements 32 that protrude from an outer periphery 26 of the base 20 of the protective cover 10, away from the interior surface 22 of the base 20. The peripheral element(s) 32 may include features (e.g., sides; discrete, spaced apart members; etc.) that are configured to be located adjacent to opposite outer peripheral edges of the mobile computing device. The base 20 and the peripheral element(s) 32 of such an embodiment of protective cover 10 define a receptacle 18. The shape and dimensions of the receptacle 18 are configured to receive a mobile computing device (not shown) in a display side-down orientation, enabling the display of the mobile computing device to be positioned adjacent to and, thus, to be protected by, the base 20 of the protective cover 10.

In the depicted embodiment, the at least one retention element 30 comprises a single peripheral element 32 that extends continuously and completely around the outer periphery 26 of the base 20 and, therefore, is configured to extend around the outer periphery of a mobile computing device (not shown) when the mobile computing device is introduced, display side-down, into the receptacle 18 of the protective cover 10.

The at least one retention element 30 (e.g., the peripheral element 32, etc.) of a protective cover 10 that incorporates teachings of the present invention may be configured to accommodate physical connections between a mobile computing device (not shown) and one or more external devices while the mobile computing device is positioned within the receptacle 18 of the protective cover. In this regard, in the embodiment depicted by FIGS. 1-5, an access feature 36 may be provided through the peripheral element 32 of the protective cover 10. While the access feature 36 is illustrated as comprising a recessed section in a bottom portion 32B of the peripheral element 32, other configurations of access features 36 are also within the scope of the present invention.

The base 20 and the retention element 30 of the protective cover 10 may be formed from rigid or substantially rigid materials, which resist deformation when localized forces are applied thereto. In addition, the retention element 30 may be rigidly associated with the base 20. Thus, the base 20 and the retention element 30 may impart the protective cover 10 with structural integrity. Examples of rigid or substantially rigid materials that may provide these characteristics include, but are not limited to, certain metals (e.g., aluminum, stainless steel, etc.), some plastics and rigid and substantially rigid composite materials (e.g., fiber-reinforced plastics, etc.), among others.

In the depicted embodiment, the base 20 and retention element 30 of the protective cover 10 form a shell 12 of the protective cover 10, which may, in some embodiments, be unitary in structure.

In addition to the shell 12, a protective cover 10 of the present invention may include a liner 14. The liner 14 may serve one or a variety of purposes. For example, the liner 14 may be formed from a material that cushions surfaces of a mobile computing device (not shown). As another example, the material from which the liner 14 is formed may enable engagement of one or more features of a mobile computing device by the retention element 30 of the protective cover 10.

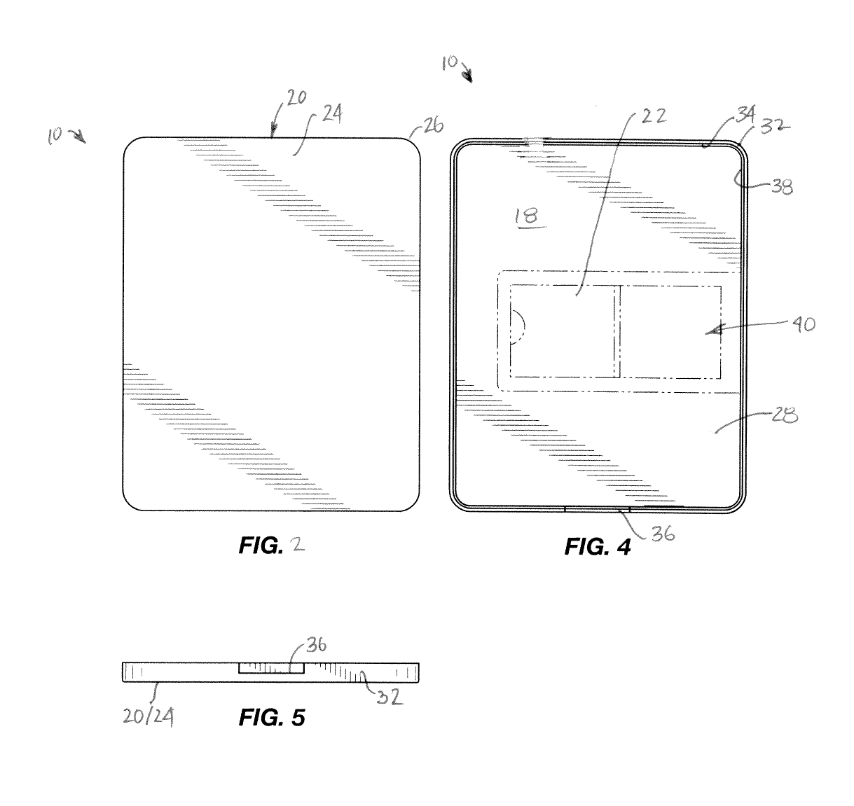

As illustrated, the liner 14 may include a base liner 28, which covers parts (as shown in FIGS. 3 and 4) or all of the interior surface 22 of the base 20. The material from which the base liner 28 is formed and the location of such a base liner 28 against the interior surface 22 of the base 20 may, in some embodiments, enable the base liner 28 to absorb any shock generated by impact on the base 20 or any other part of the shell 12.

The liner 14 may also include a peripheral liner 38, which may be positioned against or secured to an interior surface 34 of the retention element 30 (and, in the depicted embodiment, an interior surface 34 of the peripheral element 32). The peripheral liner 38 may comprise a compressible, resilient material. When used in conjunction with a rigid or substantially rigid retention element 30 that is rigidly associated with the base 20 of the protective cover 10, the peripheral liner 38 may engage at least a portion of an outer periphery of a mobile computing device (not shown) when the mobile computing device has been placed within the receptacle 18 of the protective cover 10.

A variety of materials possess desirable characteristics for the base liner 28 and the peripheral liner 38. These materials include, but are not limited to, ethylene-vinyl acetate (EVA) foam (which is commonly referred to as “foam rubber” and as “expanded rubber”), polyurethane foam (e.g., microcellular polyurethane foam; fine-celled, low compression-set, high density polyurethane foam; etc.), neoprene and a variety of other compressible, resilient materials.

Such an embodiment of protective cover 10 may be configured to protect a mobile computing device from damage (e.g., from dropping the mobile computing device (e.g., from a height of four feet or greater, from a height of six feet or greater, etc.), incurred during transportation of the mobile computing device, etc.) without significantly adding to the dimensions of a mobile computing device assembled with protective cover 10. Without limiting the scope of the present invention, in some embodiments, when a protective cover 10 is assembled with a mobile computing device, the protective cover 10 may increase a thickness of the mobile computing device by no more than about one-eighth of an inch (about 3.175 mm). Likewise, a protective cover 10 of the present invention may only add about 0.2 inches (about 5 mm) or less to each of the height and width of a mobile computing device.

In some embodiments, a protective cover 10 of the present invention also includes a support element 40. In various embodiments, a support element 40 may be configured to accommodate and/or support a mobile computing device (not shown) in a plurality of working orientations in and/or over the receptacle 18 of the protective cover.

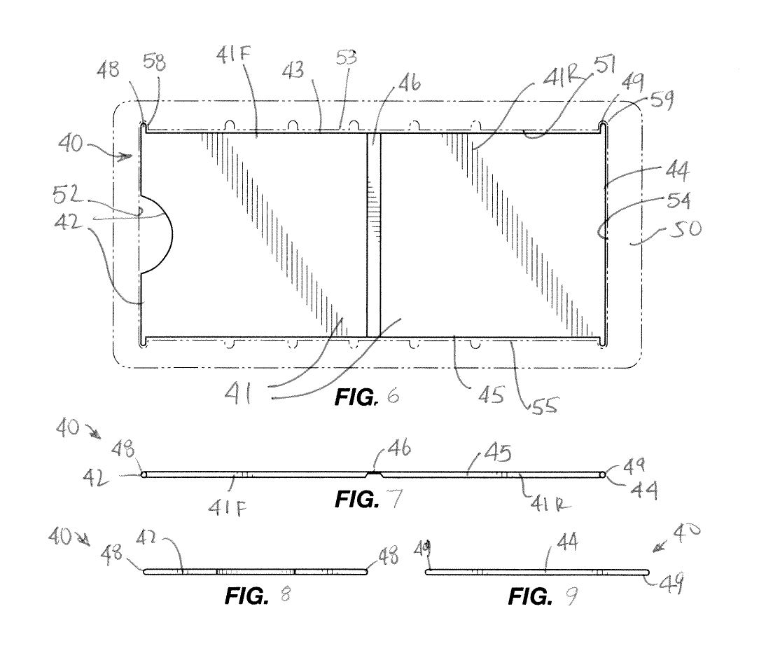

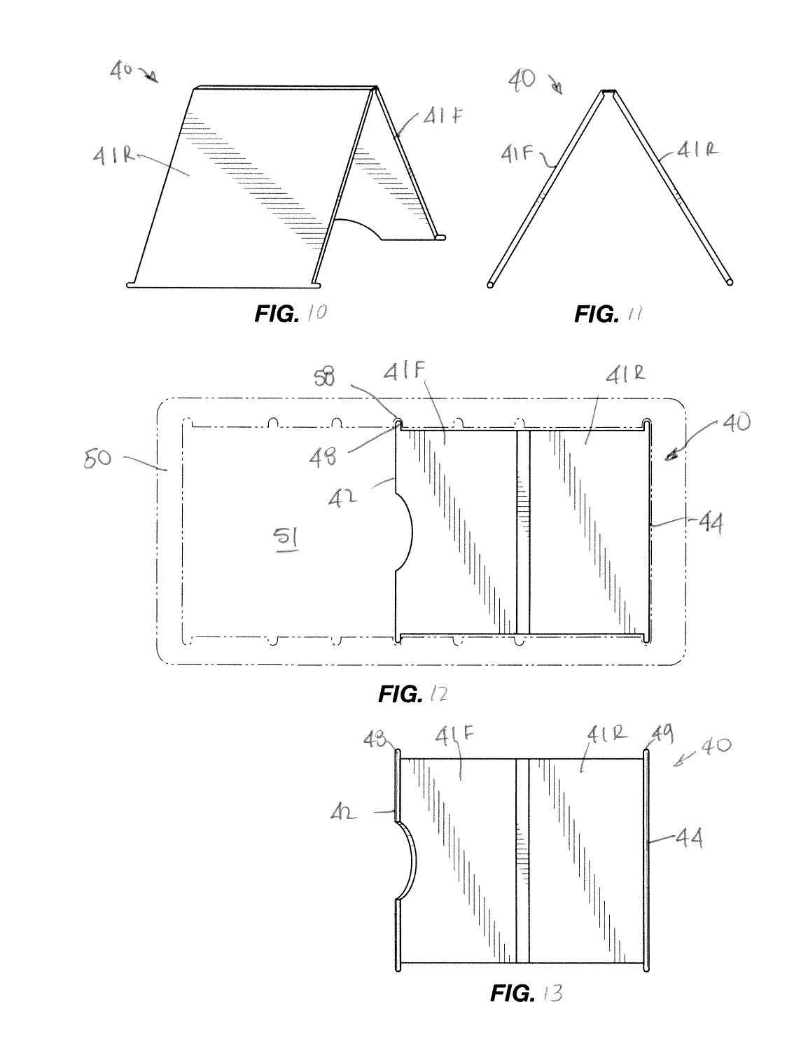

A specific, but non-limiting, embodiment of support element 40 that may be used with a protective cover 10 of the present invention is shown in FIGS. 6-13. The illustrated embodiment of support element 40 includes a flat, somewhat elongate body 41 with a front edge 42, a rear edge 44 and a hinge 46. The front edge 42 and the rear edge 44 are located at opposite ends of the support element 40. The hinge 46, which is oriented parallel or substantially parallel to the front edge 42 and the rear edge 44, is located about midway between the front edge 42 and the rear edge 44, along the length of the support element 40 and delineates a front panel 41F of the body 41 from a rear panel 41R of the body 41. While the hinge 46 is depicted as comprising a living hinge, other types of hinges are also within the scope of the present invention. In addition, in the depicted embodiment, the support element 40 includes a pair of positioning pins 48 extending in opposite directions from the side edges 43 and 45 of the body 41 of the support element 40, along the front edge 42 of the support element 40, as well as a pair retention pins 49 extending in opposite directions from the side edges 43 and 45, along its rear edge 44.

As shown in FIG. 6, the depicted embodiment of support element 40 is configured to be used in conjunction with a support base 50, which may be associated with (e.g., formed as part of, secured in place relative to, etc.) the interior surface 22 of the base 20 of the protective cover 10. The support base 50 includes a primary receptacle 51 for receiving the body 41 of the support element 40. The dimensions of the primary receptacle 51 are slightly larger than their corresponding dimensions of the body 41, enabling the primary receptacle 51 to receive the body 41 as the body 41 is oriented in a flattened, or collapsed, position. At a front end 52, within opposite sides 53 and 55 of the primary receptacle 51, the support base 50 defines a pair of opposed positioning recesses 58, which are configured to receive corresponding positioning pins 48 of the support element 40. Additional pairs of opposed positioning recesses 58 may be located at various locations in the sides 53 and 55 of the primary receptacle 51, between its front end 52 and its rear end 54. Along the rear end 54 of the primary receptacle 51, the support base 50 includes a pair of opposed retention sockets 59, which are configured to receive and retain corresponding retention pins 49 of the support element 40, while allowing the retention pins 49 to pivot.

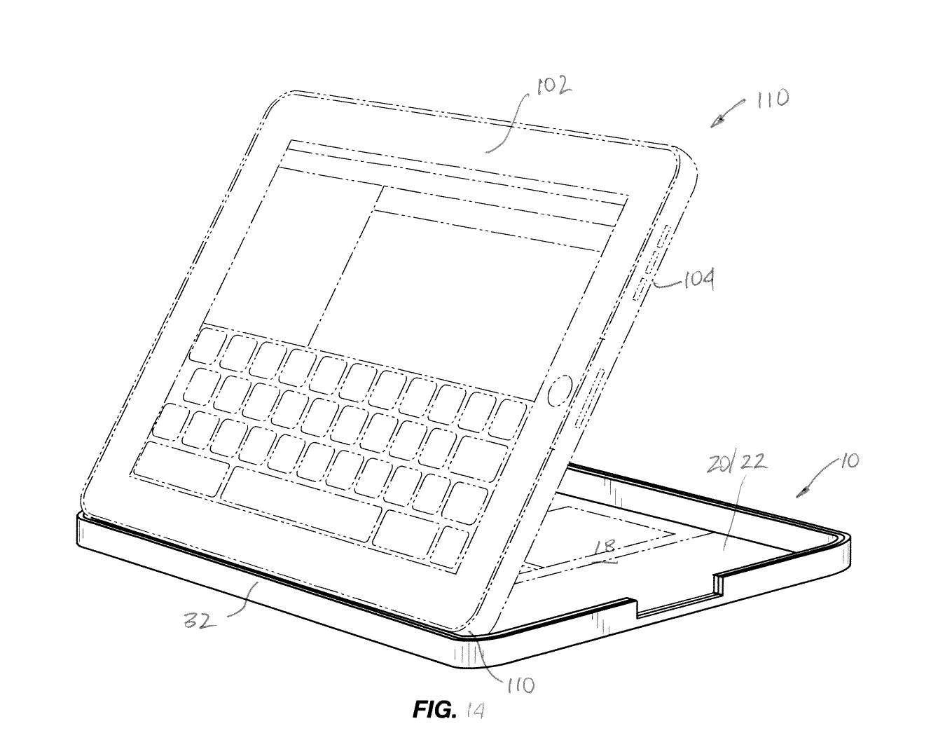

While FIGS. 6-9 show the support element 40 in a flattened, or collapsed position, FIGS. 10-13 depict the support element 40 in one of a plurality of possible raised positions. As shown in FIG. 12, in some embodiments various features of a support element 40 and/or support base 50 (e.g., the locations of positioning recesses 58 along the length of the primary receptacle 51 of the support base 50, etc.) may determine the particular raised positions (e.g., heights, angles, etc.) of the support element 40.

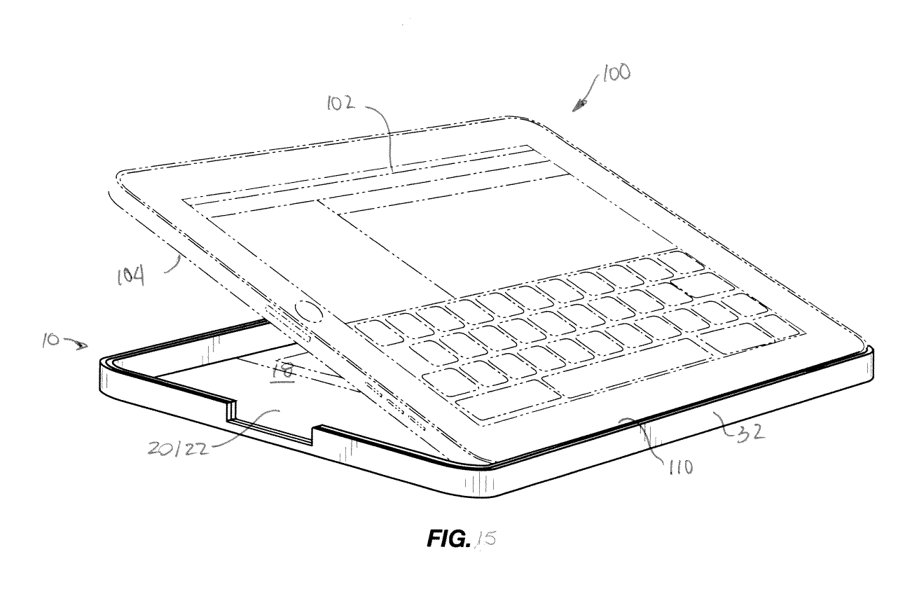

With continued reference to FIGS. 6-13, and added reference to FIGS. 14-17, with the support element 40 in a raised position, an outer peripheral edge 110 of a mobile computing device 100 may be positioned within the receptacle 18 of a protective cover 10 and adjacent to (e.g., against a peripheral liner 38 on) an interior surface 34 of a peripheral element 32 of the protective cover 10, with a back side 104 of the mobile computing device 100 resting upon the support element 40. When the back side 104 of the mobile computing device 100 is positioned against either the front panel 41F or the rear panel 41 R of the body 41 of the support element 40, the force of the mobile computing device 100 (e.g., its weight under gravity, etc.) presses the retention pins 48 against the surfaces of the retention recesses 58 in which the retention pins 48 are positioned, holding the retention pins 48 in place within their corresponding retention receptacles 58.

The angle at which a display 102 of the mobile computing device 100 is oriented may be determined, at least in part, by the position of the support element 40. A location of the outer peripheral edge 110 relative to the support element 40 (e.g., the edge 42, 44 of the support element 40 closest to where the outer peripheral edge 110 is positioned, etc.) may also at least partially determine the angle at which the display 102 of the mobile computing device 100 is oriented. For example, steep angles of orientation, such as those depicted by FIGS. 14 and 16 may be achieved positioning the outer peripheral edge 110 of the mobile computing device between the rear edge 44 of the support element 40 and the side of the peripheral element 32 located closest to the rear edge 44. Shallower angles of orientation, such as that depicted by FIG. 15, may be accomplished by positioning the outer peripheral edge 110 of the mobile computing device 100 between the front edge 42 of the support element 40 and the side of the peripheral element 32 that is located closes to the front edge 42.

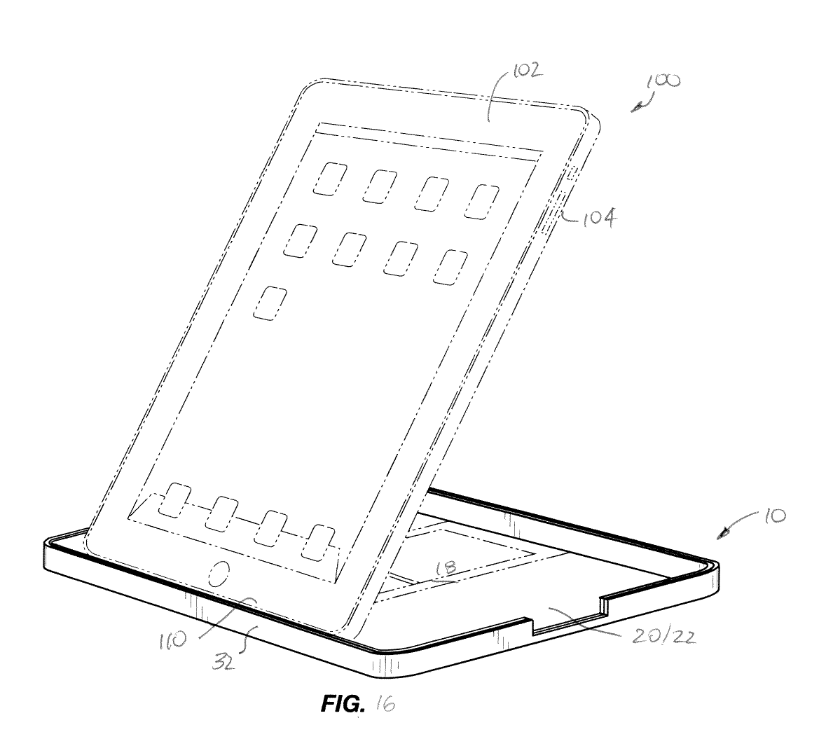

Alternatively, as shown in FIG. 17, a mobile computing device 100 may be introduced into the receptacle 18 of the protective cover 10 with the back side 104 (FIGS. 14-16) of the mobile computing device 100 parallel and adjacent to the interior surface 22 of the base 20 (FIGS. 1-5) of the protective cover 10. Such an orientation may be achieved by placing the support element 40 in a collapsed position (as shown in FIG. 6), and in embodiments of protective covers that lack support elements 40.

Turning now to FIGS. 18-22, an embodiment of a protective cover 10′ that includes an accessory 60 for a mobile computing device 100 is depicted. In the specific embodiment shown 20 and 21, the accessory 60 is a keyboard (e.g., a wireless (e.g., Bluetooth, etc.) computer keyboard, etc.). Of course, protective covers 10′ that include other types of accessories (e.g., batteries that may provide backup power for a mobile computing device; communication elements that may provide a mobile computing device with alternate and/or additional means of communication (e.g., USB or USB micro ports, HDMI ports, IEEE 1394 (i.e., FireWire, i.LINK, Lynx, etc.) interfaces, 8P8C jacks, etc.); peripheral memory devices (e.g., disk drives, hard drives, etc.); etc.) are also within the scope of the present invention.

In some embodiments, the protective cover 10′ may include one or more communication ports 70 to facilitate communication between one or more devices that are external to the protective cover 10′ and one or more accessories 60 of the protective cover 10′ and, optionally, directly or indirectly (e.g., through an accessory 60, etc.) with a mobile computing device that has been assembled with the protective cover 10′. Each communication port 70 may be accessible through a peripheral element 32′ of the protective cover 10′, and may be associated with an accessory 60 in a manner known in the art. In embodiments where an accessory 60 of the protective cover 10′ requires power, at least one communication port 70 of the protective cover 10′ may include a power inlet of any suitable type known in the art (e.g., the illustrated USB port, a jack for a DC power converter, etc.), and may be associated with the accessory in a manner that enables power to be provided directly or indirectly (e.g., through one or more batteries, etc.) to the accessory 60.

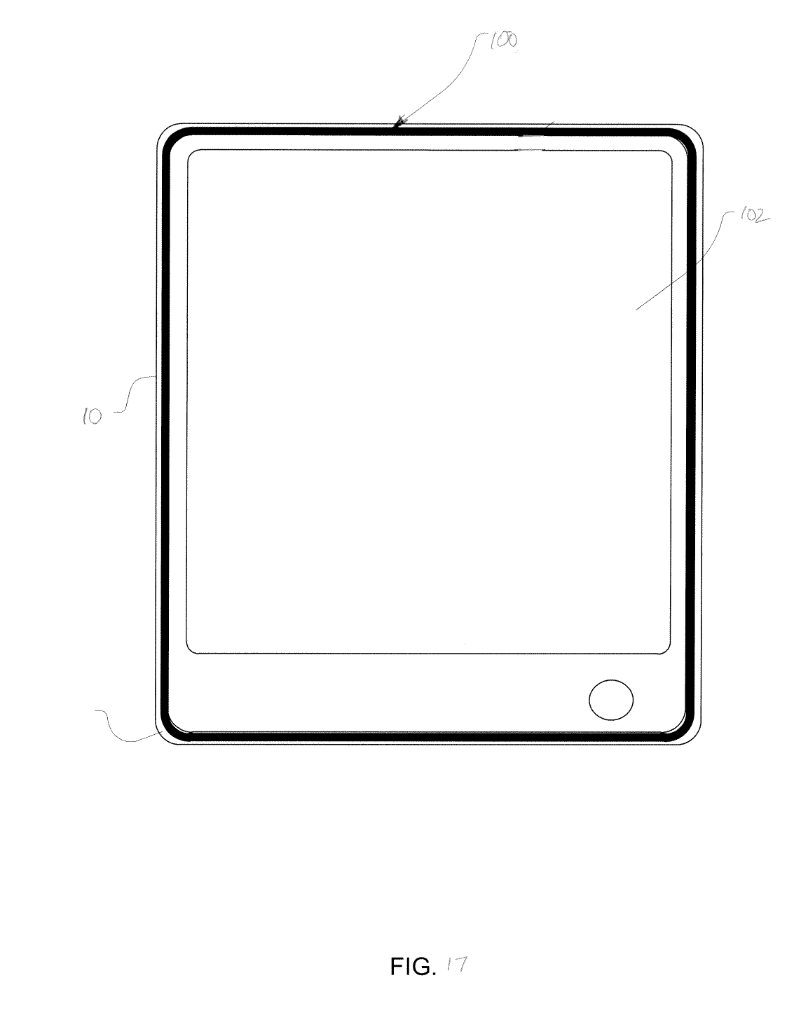

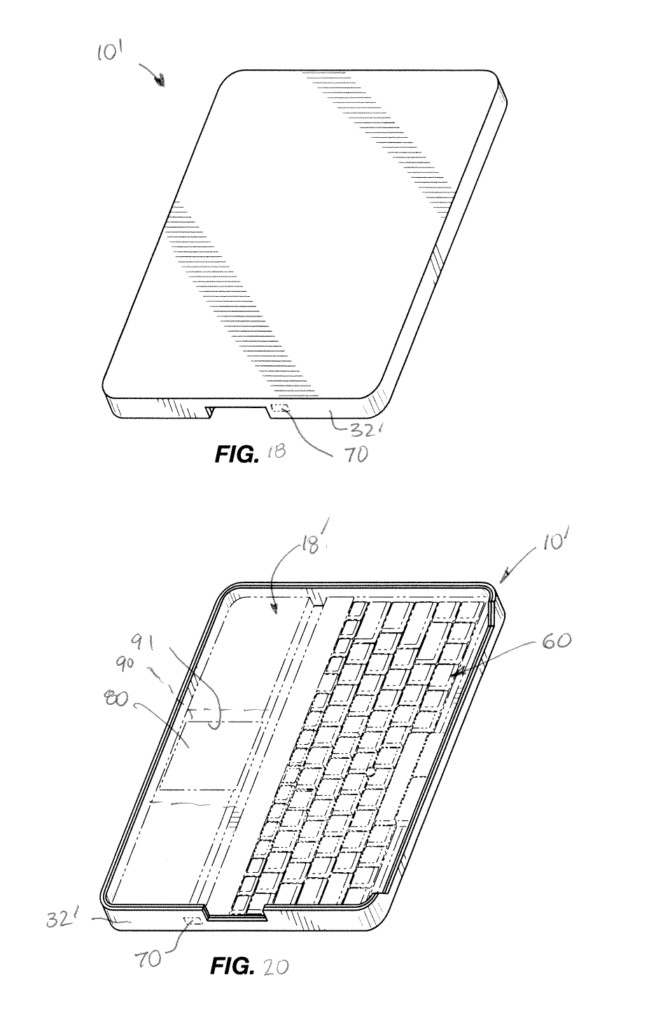

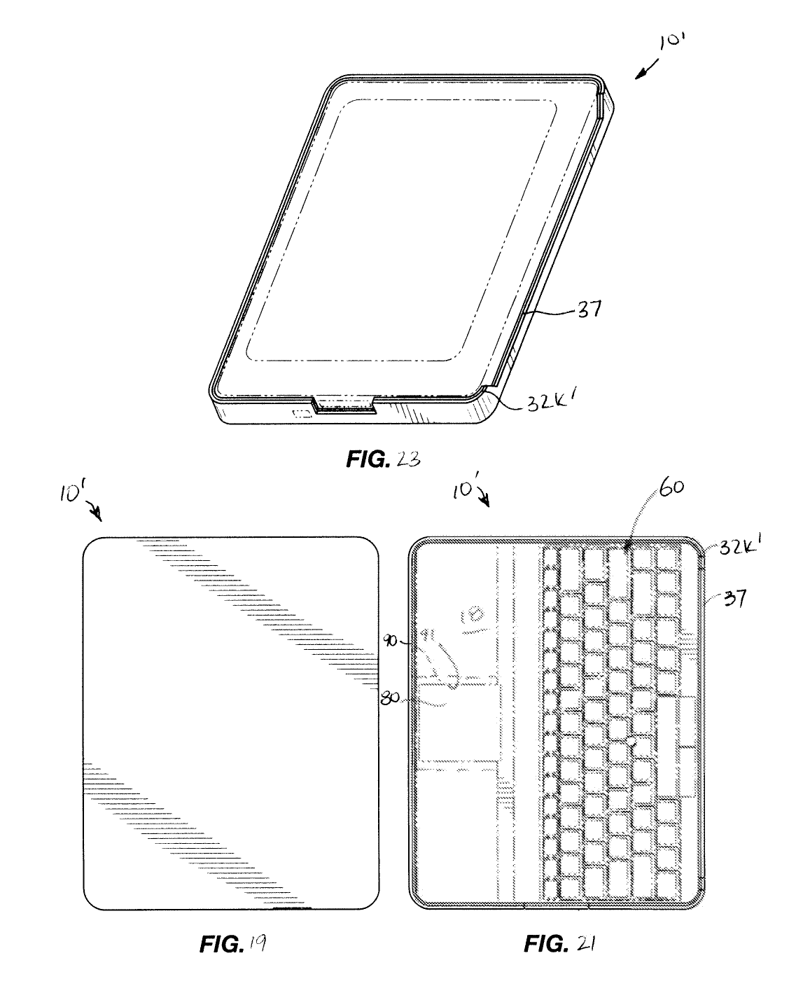

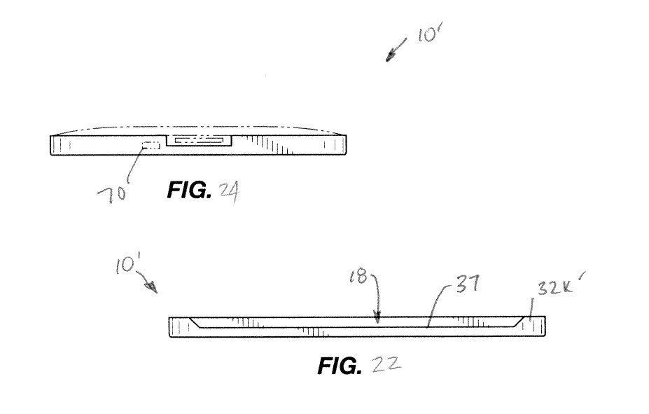

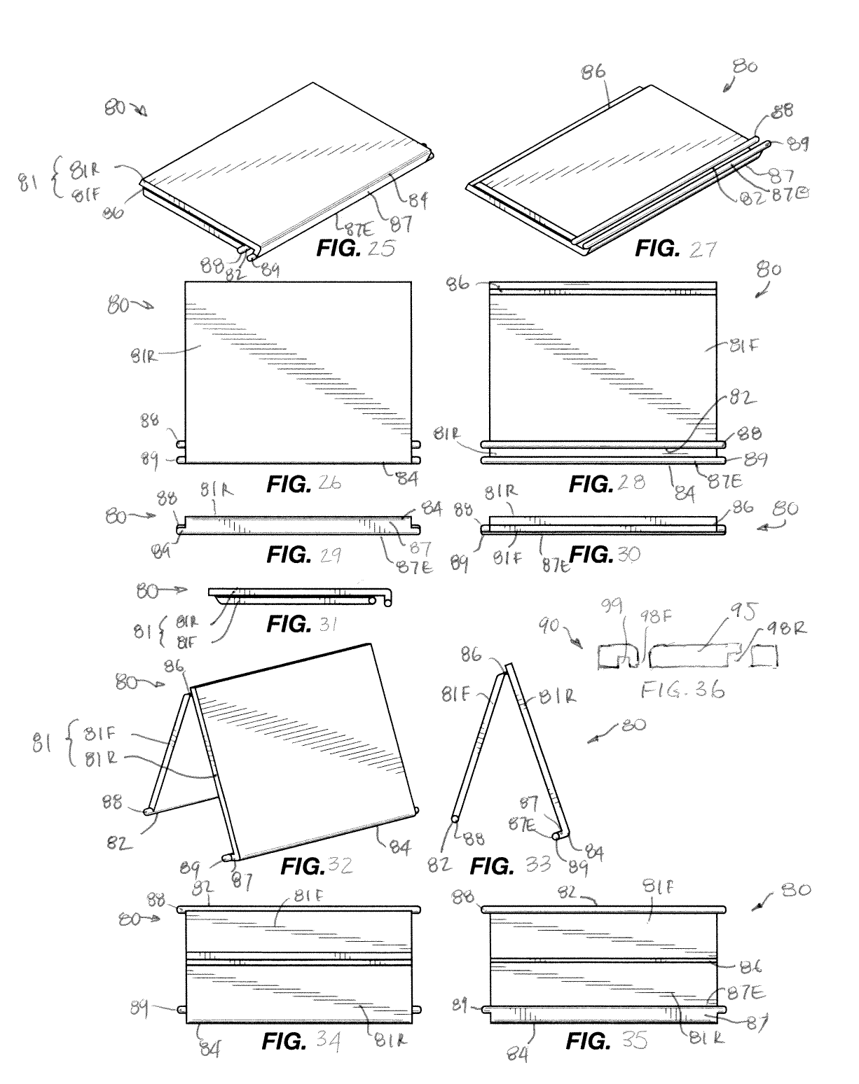

In embodiments where the accessory 60 comprises a keyboard, such as that depicted by FIGS. 20 and 21, the protective cover 10′ may be configured to enable a user to comfortably access and use the keyboard. Without limiting the scope of the present invention, a side 32K′ of the peripheral element 32 located next to the keyboard may include a recess 37 that extends along the entire width or most of the width of the keyboard. The recess 37 be located at an elevation that is about the same as or beneath an elevation of the upper surfaces of the keyboard.

The upper surfaces of the keyboard may be recessed within the receptacle 18′ of the protective cover 10′ a sufficient depth that the receptacle 18′ may also accommodate a mobile computing device (not shown).

In addition to carrying one or more accessories 60, such as the depicted keyboard, the receptacle 18′ of a protective cover 10′ of the present invention may carry components (e.g., a battery, a circuit board and the electronics carried by the circuit board, wiring, switches, indicator lights, etc.) associated with the accessory. In addition, the receptacle 18′ may carry other accessories 60 for the mobile computing device.

Additionally, in embodiments where the protective cover 10′ includes a keyboard, the receptacle 18′ may include an edge retention element 62, which is configured to receive and at least partially retain an edge of a mobile computing device (not shown), adjacent to a top edge of the keyboard. In the embodiment illustrated by FIGS. 20 and 21, the edge retention element 62 comprises a slot recessed in a bottom surface 19′ of the receptacle 18′. On an opposite side of the edge retention element 62 from the keyboard, the receptacle 18′ of the protective cover 10′ may carry a support element 80 and a base 90 with which the support element 80 is assembled.

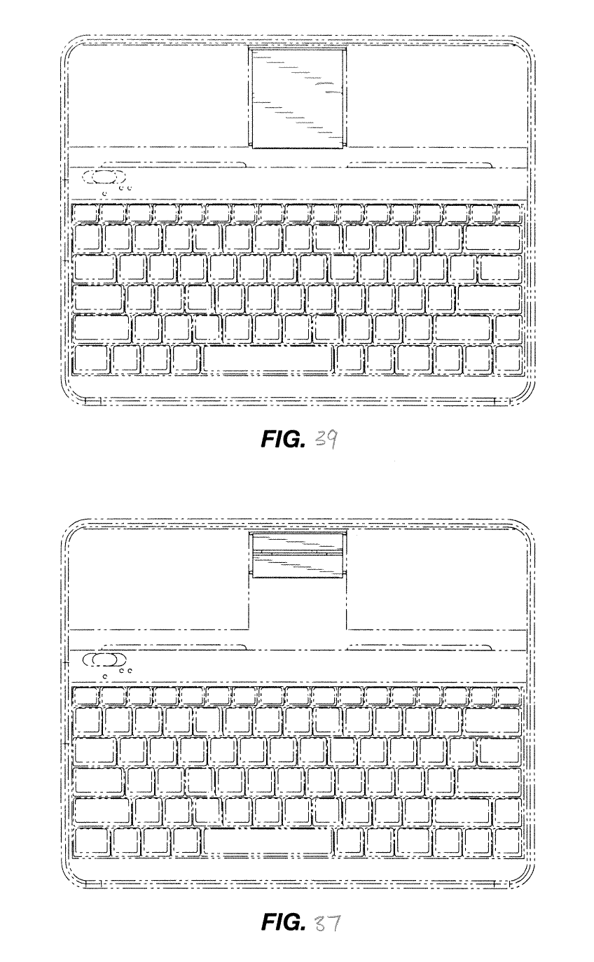

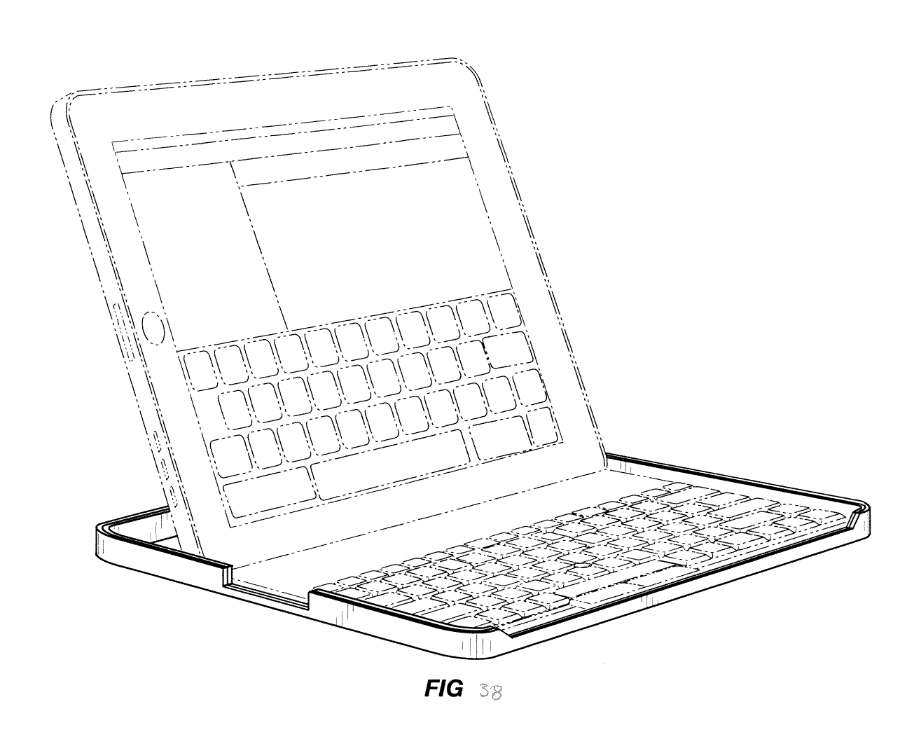

A specific, but non-limiting, embodiment of a support element 80 is depicted by FIGS. 25-35, and a specific embodiment of support base 90 that is configured for use with the support element 80 is shown in FIG. 36. FIGS. 25-31 show the support element 80 in a folded, or collapsed position, while FIGS. 32-35 depict the support element 80 in an at least partially unfolded, raised position.

The support element 80 includes a body 81 with a front panel 81F and a rear panel 81R. The front and rear panels 81F and 81R are joined by a hinge 86 (e.g., a living hinge, etc.). As illustrated, the rear panel 81R is longer than the front panel 81F. When the support element 80 is in its folded position, as shown in FIGS. 25-31, the rear panel 81R is positioned against the front panel 81F, with a rear edge 84 of the rear panel 81R located laterally beyond a front edge 82 of the front panel 81F, and a lip 87 at the rear edge 84 protruding to a location laterally adjacent to the front edge 82.

A pair of positioning pins 88 is located along the front edge 82, with the positioning pins 88 protruding in opposite directions from the sides 83 and 85 of the body 81 of the support element 80. In addition, a pair of retention pins 89, located along the edge 87E of the lip 87, protrudes in opposite directions from the sides 83 and 85 of the body 81 of the support element 80. With the support element 80 is in the folded position, the retention pins 89 are located at an elevation that is the same as or below the elevation of the positioning pins 88.

The positioning pins 88 and the retention pins 89 of the support element 80 are configured to cooperate with corresponding features of a complementarily configured support base 90. FIG. 36 illustrates an embodiment of such a support base 90. In particular, with continuing reference to FIGS. 25-35, FIG. 36 illustrates the features of a lateral side 95 of a primary receptacle 91 (FIGS. 20 and 21) of an embodiment of a base 90 that may be used with the embodiment of support element 80 shown in FIGS. 25-35. An unillustrated, opposite side of the primary receptacle 91 is a mirror image of side 95. Side 95 includes a retention socket 99 that receives and retains a retention pin 89 of the support element 80 in a manner that enables the retention pin 89 to pivot. A collapsed position positioning receptacle 98F is located just in front of the retention socket 99, and is configured to removably receive a positioning pin 88 of the support element 80 when the support element 80 is in a folded position, and its body 81 is placed within the primary receptacle 91. A raised position positioning receptacle 98R, which is located in front of the collapsed position positioning receptacle 98F, has a shape (e.g., the illustrated reverse-L shape, etc.) that enables the positioning pin 88 to lock into position as a force (e.g., the force of a mobile computing device, etc.) is applied to the front panel 81F of the body 81 of the support element 80. The positioning pin 88 may be removed from the raised position positioning receptacle 98R by moving the front panel 81F forward, then lifting the positioning pin 88 out of the raised position positioning receptacle 98R. Although FIG. 36 illustrates an embodiment of support base 90 that includes only one raised position positioning receptacle 98R, embodiments of support bases that include more than one raised position positioning receptacle are also within the scope of the present invention.

The configurations of the support element 80 and the support base 90 enable the support element 80 to rest flat, parallel to the bottom surface 19′ of the receptacle 18′ and, in some embodiments, substantially flush with bottom surface 19′ of the receptacle 18′ while the support element 80 is in its folded, or collapsed, position.

FIG. 37 depicts the support element 80 in a raised position. With the support element 80 in the raised position, an outer peripheral edge 110 of a mobile computing device 100 may be engaged by an edge retention element 62 within the receptacle 18′ of a protective cover 10′, and a back side 104 of the mobile computing device 100 may be positioned against the front panel 81F of the support element 80, placing a display 102 of the mobile computing device 100 in a working position having a substantially upright angle, as shown in FIG. 38.

FIG. 39 shows a protective cover 10′ with the support element 80 in a folded, or collapsed, position. When the support element 80 is in the collapsed position, a mobile computing device 100 may be introduced into the receptacle 18′ of the protective cover 10′, with a display 104 (FIG. 39) of the mobile computing device 100 covered by the protective cover 10′, as shown in FIGS. 23 and 24. When such an embodiment of a protective cover 10′ is assembled with a mobile computing device 100, the protective cover 10′ may prevent damage to the mobile computing device 100 without significantly adding to the dimensions of the mobile computing device 100. In some embodiments, an assembly including the protective cover 10′ and a mobile computing device 100 may have a thickness that exceeds the thickness of the mobile computing device 100 alone by only about one-fourth of an inch (about 6.35 mm) or less. Similarly, the protective cover 10′ may only add about 0.2 inches (about 5 mm) or less to each of the height and width of the mobile computing device 100.

When disassembly of the protective cover 10′ from the mobile computing device 100 is desired, a user may grasp adjacent areas of the protective cover 10′ and a feature of the mobile computing device 100 exposed through or beyond the protective cover 10′ (e.g., an outer peripheral edge 110 adjacent to a communication port 108 of the mobile computing device 100, which is exposed through an access feature 36 of the protective cover 10′, etc.), then pull the grasped areas in opposite directions.

Although the foregoing description contains many specifics, these should not be construed as limiting the scope of the invention or of any of the appended claims, but merely as providing information pertinent to some specific embodiments that may fall within the scopes of the invention and the appended claims. Features from different embodiments may be employed in combination. In addition, other embodiments of the invention may also be devised which lie within the scopes of the invention and the appended claims. The scope of the invention is, therefore, indicated and limited only by the appended claims and their legal equivalents. All additions, deletions and modifications to the invention, as disclosed herein, that fall within the meaning and scopes of the claims are to be embraced by the claims.

What is claimed:

1. A protective cover for a mobile computing device, comprising:
a rigid base including an interior surface configured to be positioned over a display of a mobile computing device; and
at least one retention element configured to engage a feature of the rigid base to secure the rigid base in place over the display of the mobile computing device.

2. The protective cover of claim 1, further comprising:
a liner a least partially covering the interior surface and comprising a material configured to absorb shock generated by impacts upon at least one of the rigid base and the at least one retention element.

3. The protective cover of claim 1, wherein the at least one retention element comprises at least one peripheral element configured to be located adjacent to at least one outer peripheral edge of the mobile computing device.

4. The protective cover of claim 3, wherein the at least one peripheral element includes features configured to be positioned adjacent to opposite outer peripheral edges of the mobile computing device.

5. The protective cover of claim 4, wherein the features of the at least one peripheral element are substantially rigid.

6. The protective cover of claim 5, further comprising:
a liner at least partially covering interior surfaces of the feature of the at least one peripheral element and comprising a material that will engage the opposite outer peripheral edges of the mobile computing device.

7. The protective cover of claim 6, wherein the material of the liner is compressible and resilient.

8. The protective cover of claim 1, further comprising:
at least one accessory for enhancing or adding to a functionality of the mobile computing device.

9. The protective cover of claim 8, wherein the at least one accessory comprises at least one of a keyboard, a battery, a memory device, and an additional communication port.

10. The protective cover of claim 9, configured to be assembled with the mobile computing device without adding more than about one-fourth of an inch to a thickness of the mobile computing device.

11. The protective cover of claim 1, configured to be assembled with the mobile computing device without adding more than about one-eighth of an inch to a thickness of the mobile computing device.

12. A mobile computing system, comprising:
a mobile computing device; and
a protective cover for the mobile computing device, the protective cover including a rigid base configured to be positioned over a display of the mobile computing device,
the mobile computing device and the protective cover having:
a protected arrangement in which the base of the protective cover is positioned over the display of the mobile computing device; and
a working arrangement, in which the protective cover orients the display of the mobile computing device in a working orientation.

13. The mobile computing system of claim 12, wherein the protective cover comprises a rigid metal.

14. The mobile computing system of claim 13, wherein the protective cover is configured for assembly with the mobile computing device in the protected arrangement in a manner that increases a thickness of the mobile computing device by no more than about one-fourth of an inch.

15. The mobile computing system of claim 12, wherein the protective cover carries at least one accessory for enhancing or adding to a functionality of the mobile computing device.

16. The mobile computing system of claim 15, wherein the at least one accessory comprises at least one of a keyboard, a battery, a memory device, and an additional communication port.

17. The mobile computing system of claim 12, further comprising:
at least one external device in communication with the mobile computing device.

18. A method for protecting a mobile computing device, comprising:
placing a rigid protective cover over a display of a mobile computing device;
placing a rigid peripheral element of the rigid protective cover around outer peripheral edges of the mobile computing device, a liner on an interior surface of the rigid peripheral element engaging the outer peripheral edges of the mobile computing device and retaining the rigid protective cover in place over the display of the mobile computing device.

19. The method of claim 18, wherein placing the rigid peripheral element comprises introducing the mobile computing device into a receptacle defined by a rigid peripheral element that entirely surrounds an outer periphery of the mobile computing device around the outer peripheral edges of the mobile computing device.

20. The method of claim 18, wherein placing the rigid protective cover and placing the rigid peripheral element comprise assembling a protective cover with the mobile computing device adding more than about one-fourth of an inch to a thickness of the mobile computing device.
